(19) United States
(12) Patent Application Publication
(10) Pub. No.: US 2006/0071182 A1
(43) Pub. Date: Apr. 6, 2006

(54) Method of processing semiconductor apparatus

(75) Inventors: Naoto Sugiura, Kyoto-shi (JP); Yuichi Kitamura, Nagaokakyo-shi (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/241,944

(22) Filed: Oct. 4, 2005

(30) Foreign Application Priority Data
Oct. 4, 2004 (JP) 2004-291305

(51) Int. Cl. H01J 37/08

(52) U.S. Cl. 250/492.21; 250/492.2

(57) ABSTRACT

The present invention relates to a method (apparatus) of processing a semiconductor apparatus, wherein a processing beam is irradiated on a semiconductor apparatus comprising an insulation film and a conductor embedded in the insulation film while the insulation film is scanned from a surface side thereof so that the insulation film and the conductor are burned and cut. The processing method (apparatus) comprises a scanning region setting step for setting a scanning region of the processing beam to a region where a scanning column direction thereof traverses a cut section of the conductor and a beam scanning step for irradiating the processing beam for scanning along the set scanning region, wherein the processing beam used for scanning a final scanning column is supplied with a dosage capable of eliminating a conductive residue generated by the irradiation of the processing beam on the conductor and attached to a cut end surface facing the final scanning column in the beam scanning step.

### BACKGROUND OF THE INVENTION

1. Field of the Invention

The present invention relates to a method of processing a semiconductor apparatus and an apparatus for processing the semiconductor apparatus which are employed for cutting a conductor in an interlayer insulation film in the semiconductor apparatus such as a semiconductor chip.

2. Description of the Related Art

When a conductor in a semiconductor apparatus is conventionally cut by means of the Focused Ion Beam (FIB) (hereinafter, such a process is referred to as FIB process), assist gas chemically reacting with a conductor material is used. In the case of cutting an aluminum wiring, for example, assist gas made of chlorine or bromine is used. As another example, a method of insulating the conductor material using oxygen as the assist gas, which is recited in No. 04-98747 of the Publication of the Unexamined Japanese Patent Applications, is available.

In recent years, copper having a relatively low resistance is used as the conductor in order to cope with an increasingly higher performance of the semiconductor apparatus. However, copper is characterized in that fragments generated from the conductor cut in the FIB process (hereinafter, referred to as conductive residue) are easily dispersed around. The dispersed conductive residue, which is attached to a cut section of the conductor and a side surface of a cut hole, becomes an obstacle in electrically isolating the conductor.

For example, FIGS. 11A and 11B show a state where an interlayer insulation film 1 is cut to be removed from a surface of the semiconductor apparatus so that a conductor 2 as a subject to be cut is exposed and a processing box 4 is disposed in a cut section. A reference symbol 1a denotes a cut hole in the interlayer insulation film 1. The processing box 4 denotes a processing region shown on a setting screen of a beam region designating apparatus. When the processing box 4 is used so that a processing beam cuts the conductor 2, a conductive residue 2b is dispersed around the processed section as shown in FIGS. 11C and 11D. As a result, the conductor 2 to be cut is short-circuited with respect to other peripheral parts due to the conductive residue 2b, which results in a failure of the electrical isolation.

When aluminum is used as the conductor, chlorine gas or bromine gas chemically reacting with the aluminum is used as the assist gas, the dispersion of the conductive residue can be controlled. However, there does not exist any assist gas capable of satisfactorily preventing the dispersion in the case of using the copper as the conductor.

### SUMMARY OF THE INVENTION

Therefore, a main object of the present invention is to provide a method of and an apparatus for processing a semiconductor apparatus capable of precisely achieving an electrical isolation after a cutting process.

A method of processing a semiconductor apparatus according to the present invention is a semiconductor apparatus processing method wherein a processing beam is irradiated on a semiconductor apparatus comprising an insulation film and a conductor embedded in the insulation film while the insulation film is scanned from a surface side thereof so that the insulation film and the conductor are burned and cut. The processing method according to the present invention comprises a scanning region setting step for setting a scanning region of the processing beam to a region where a scanning column direction thereof traverses a cut section of the conductor and a processing beam scanning step for irradiating the processing beam for the scan along the set scanning region.

In the beam scanning step, the processing beam used for scanning a final scanning column is supplied with a dosage capable of eliminating a conductive residue generated by the irradiation of the processing beam on the conductor and attached to a cut end surface facing the final scanning column in the beam scanning step.

An apparatus for processing the semiconductor apparatus corresponding to the semiconductor processing method comprises a scanning region setting device for setting the scanning region of the processing beam to the region where the scanning column direction thereof traverses the cut section of the conductor and a processing beam scanning device for irradiating the processing beam for scanning along the set scanning region.

The beam scanning device supplies the dosage capable of eliminating the conductive residue generated by the irradiation of the processing beam on the conductor and attached to the cut end surface facing the final scanning column to the processing beam used for scanning the final scanning column.

Thereby, the conductor can be cut in the unfailingly electrically isolated state without any conductive residue attached to the cut end surface.

In the beam scanning step, the scanning region is beam-scanned a plurality of times, and the processing beam irradiated on each of the final scanning columns beam-scanned the plurality of times may be supplied with the dosage capable of eliminating the conductive residue generated by the irradiation of the processing beam on the conductor and attached to the cut end surface facing the final scanning column, wherein the aforementioned effect can be exerted in the same manner.

The beam scanning step preferably includes an insulation film eliminating step in which the processing beam is irradiated on the insulation film covering the cut section of the conductive film so that a cut hole for exposing the cut section of the conductive film is formed in the insulation film and a conductive film cutting step in which the conductive film exposed out of a bottom section of the cut hole is cut. In this constitution, the processing beam used for scanning the final scanning column is supplied with the dosage capable of eliminating the conductive residue generated by the irradiation of the processing beam on the conductor and attached to the cut end surface facing the final scanning column in the conductive cutting step.

It is preferable that the scanning region setting step be implemented after the insulation film eliminating step, and the scanning region be set to a region where the final scanning column falls on a side surface of the cut hole or a region where the final scanning column is disposed slightly closer to the inside of the insulation film than the side surface of the cut hole in the scanning region setting step.

It is preferable that a step of forming a insulation thin film for covering the exposed conductive film at the bottom section of the cut hole be included prior to the conductive film cutting step, or the insulation thin film for covering the conductive film remain at the bottom section of the cut hole in the insulation film eliminating step. In the presence of the insulation film on the exposed conductive film, the cut section of the conductor is not limited to a close proximity of the cut hole of the interlayer insulation film. Thereby, a cutting depth with respect to the interlayer insulation film under the conductor can be easily controlled, which prevents a possible damage on the conductor as the under layer.

A method of processing the semiconductor apparatus according to the present invention comprises a conductor cutting step in which a processing beam is irradiated on a semiconductor apparatus comprising an insulation film and a conductor embedded in the insulation film from a surface side of the insulation film so that the insulation film and the conductor are burned and cut, a cleaning scanning region setting step in which a scanning region of a cleaning beam is set to a region where a scanning column direction thereof traverses a cut section of the conductor and a final scanning column thereof falls on a cut end surface of the conductor or the final scanning column is disposed slightly closer to an inner side of the insulation film than a side surface of the cut hole, and a cleaning beam scanning step for irradiating the cleaning beam for scanning along the set scanning region.

In the cleaning beam scanning step, the cleaning beam used for scanning the final scanning column is supplied with the dosage capable of eliminating the conductive residue generated by the irradiation of the processing beam on the conductor and attached to the cut end surface facing the final scanning column.

An apparatus for processing the semiconductor apparatus corresponding to the foregoing method of processing the semiconductor apparatus comprises a conductor cutting device for irradiating the processing beam on the semiconductor apparatus comprising the insulation film and the conductor embedded in the insulation film from the surface side thereof so that the insulation film and the conductor are burned and cut, a cleaning scanning region setting device for setting the scanning region of the cleaning beam to the region where the scanning column direction thereof traverses the cut section of the conductor and the final scanning column thereof falls on the cut end surface of the conductor or the region where the final scanning column is disposed slightly closer to the inside of the insulation film than the side surface of the cut hole, and a cleaning beam scanning device for irradiating the cleaning beam for scanning along the set scanning region.

The cleaning beam scanning device supplies the cleaning beam used for scanning the final scanning column with the dosage capable of eliminating the conductive residue generated by the irradiation of the processing beam on the conductor and attached to the cut end surface facing the final scanning column.

In the foregoing constitution, the interlayer insulation film under the conductor layer can also be cut when the conductor is burned and cut, which assures a larger cutting region in the conductor. However, there is often an energy shortage in the processing beam, which makes it easy for the conductive residue to be attached. Therefore, the beam scanning is used for cleaning so as to eliminate the conductive residue. As a result, the conductor can be cut in the unfailingly electrically isolated sate.

The conductive film cutting step preferably includes an insulation film eliminating step in which the processing beam is irradiated on the insulation film covering the cut section of the conductive film so that the cut hole for exposing the cut section of the conductive film is formed in the insulation film, a step of forming an insulation thin film for covering the exposed conductive film at the bottom section of the cut hole and a conductive film cutting step for cutting the conductive film exposed out of the bottom section of the cut hole.

The conductive film cutting step preferably includes an insulation film eliminating step for irradiating the processing beam on the insulation film covering the cut section of the conductive film so that the cut hole for exposing the cut section of the conductive film is formed in the insulation film and a conductive film cutting step for cutting the conductive film exposed out of the bottom section of the cut hole, wherein an insulation thin film for covering the conductive film remains at the bottom section of the cut hole in the insulation film eliminating step. In the presence of the insulation film on the exposed conductive film, the cut section of the conductor is not limited to the close proximity of the cut hole of the interlayer insulation film. Thereby, the cutting depth with respect to the interlayer insulation film under the conductor can be easily controlled, which prevents a possible damage on the conductor as the under layer.

The conductor cutting step preferably includes a processing beam scanning region setting step for setting the scanning region of the processing beam to the region where the scanning column direction thereof traverses a cut section of the conductor and a processing beam scanning step for irradiating the processing beam for scanning along the set scanning region, wherein the scanning region of the processing beam is shifted so as to set the scanning region of the cleaning beam in the cleaning scanning region setting step, and the cleaning beam is used for the scan along the scanning region of the cleaning beam set by shifting the scanning region of the processing beam in the cleaning beam scanning step. Thereby, the cleaning beam scanning step results in executing a beam shift processing in which the processing beam is merely shifted, which alleviates an influence from the cutting process on the interlayer insulation film under the conductor. As a result, the cutting depth with respect to the interlayer insulation film under the conductor can be easily controlled, which prevents a possible damage on any conductor as the under layer.

It is preferable that an insulator depositing gas be supplied to the cut section of the conductor after the cleaning beam scanning step is implemented so that an insulator is deposited in the cut section through a reaction generated by the insulator depositing gas with respect to the cleaning beam. Thereby, the insulator depositing gas is made to react with the cleaning beam in the cut hole so that the cut hole is filled with the insulator. As a result, the electrical insulation of the conductor can be further ensured, and an efficiency of processing can be increased.

It is preferable that the insulator depositing gas be supplied to the cut section of the conductor after the beam scanning step is implemented so that the insulator is deposited in the cut section through the reaction generated by the insulator depositing gas with respect to the processing beam. Thereby, the insulator depositing gas is made to react with the processing beam in the cut hole so that the cut hole is filled with the insulator. As a result, the electrical insulation of the conductor can be further ensured, and the processing efficiency can be increased.

It is preferable that a tilting generated in the cut end surface by the focused beam be cancelled in the beam scanning step and the cleaning beam scanning step and the semiconductor apparatus be tilted instead in such manner that the cut end surface is vertical to the surface of the insulation film.

It is preferable that a direction of the beam irradiation be set to such a direction that the cut end surface is vertical to the surface of the insulation film in the beam scanning step or the cleaning beam scanning step. Thereby, the side surface of the cut hole is orthogonal to the surface of the conductor so that the attachment of the conductive residue to the side surface can be controlled and the electrical insulation can be further ensured.

According to the present invention, the short cut resulting from the dispersion of the conductive residue can be prevented, and the electrical insulation can be realized by cutting the copper wiring. Further, it becomes unnecessary to use the assist gas in the cutting process. Other than the foregoing effects, the conductor can be electrically insulated while the side etching generated from the interlayer insulation film formed from a material having a low dielectric constant is prevented. Even a plurality of conductors stacked on one another can be cut without generating the short circuit among the conductors.

The cutting process can be successfully carried out in any conductor material other than copper.

As described, the present invention relates to a technology for cutting the conductor using the beam and thereby electrically insulating the conductor, and is particularly effective for the semiconductor apparatus in which copper is used increasingly often as the conductor material. The present invention can also be applied when a conductor in a circuit substrate is cut.

### BRIEF DESCRIPTION OF THE DRAWINGS

These and other objects as well as advantages of the invention will become clear by the following description of preferred embodiments and explicit in the appended claims of the invention. Many other benefits of the invention not described in this specification will come to the attention of those skilled in the art upon implementing the present invention.

FIG. 1A-1F are schematic illustrations of a beam scanning method according to preferred embodiments of the present invention and a processing shape in the method.

FIG. 2A is a plan view illustrating a semiconductor processing method and apparatus according to an embodiment 1 of the present invention.

FIGS. 2B-2C are sectional views illustrating the semiconductor processing method and apparatus according to the embodiment 1.

FIGS. 3A-3D are sectional views illustrating a semiconductor processing method and apparatus according to an embodiment 2 of the present invention.

FIGS. 4A and 4C are sectional views illustrating a semiconductor processing method and apparatus according to an embodiment 3 of the present invention.

FIG. 4B is a plan view illustrating the semiconductor processing method and apparatus according to the embodiment 3.

FIGS. 5A and 5C are sectional views illustrating a semiconductor processing method and apparatus according to an embodiment 4 of the present invention.

FIG. 5B is a plan view illustrating the semiconductor processing method and apparatus according to the embodiment 4.

FIGS. 6A and 6C are sectional views illustrating a semiconductor processing method and apparatus according to a modified embodiment of the embodiment 4.

FIG. 6B is a plan view illustrating a semiconductor processing method and apparatus according to the modified embodiment of the embodiment 4.

FIGS. 7A, 7, B 7E and 7F are sectional views illustrating a semiconductor processing method and apparatus according to an embodiment 5 of the present invention.

FIGS. 7C and 7D are plan views illustrating a semiconductor processing method and apparatus according to an embodiment 6 of the present invention.

FIGS. 8A-8C are sectional views of a semiconductor processing method and apparatus according to an embodiment 7 of the present invention.

FIGS. 9A-9C are sectional views of a semiconductor processing method and apparatus according to an embodiment 8 of the present invention.

FIGS. 10A and 10B are sectional views illustrating a semiconductor processing method (apparatus) (sectional surface is orthogonally formed as a result of tilting the beam) according to an embodiment 9 of the present invention.

FIG. 11 shows problems generated when a conductor in a semiconductor apparatus is cut according to a conventional technology.

### DETAILED DESCRIPTION OF THE INVENTION

Hereinafter, preferred embodiments of a semiconductor processing method and an apparatus for implementing the method according to the present invention are described referring to the drawings.

### Embodiment 1

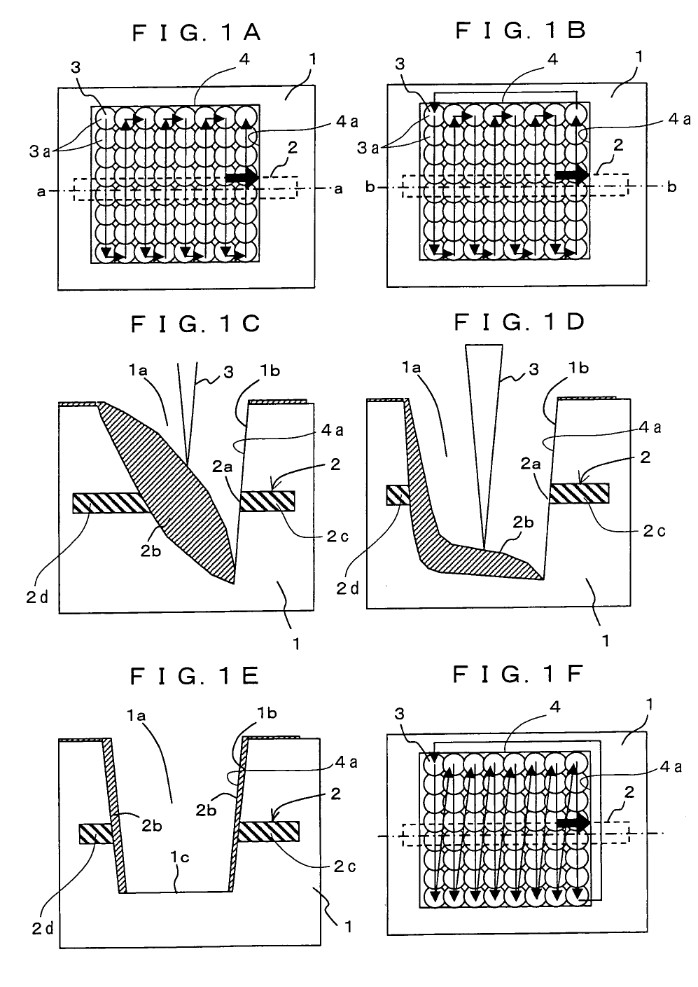

A semiconductor processing method (apparatus) according to an embodiment 1 of the present invention is described referring to FIGS. 1A through 1F. In these drawings, a reference numeral 1 denotes an interlayer insulation film constituting a semiconductor apparatus, a reference numeral 2 denotes a conductor embedded in the interlayer insulation film 1, and a reference numeral 3 denotes a focused ion beam (FIB) for processing the interlayer insulation film. The focused ion beam 3 used for the processing is hereinafter referred to as a processing beam 3. A reference symbol 1a denotes a cut hole formed in the interlayer insulation film 1 by the processing beam 3. A reference numeral 20 denotes a region to which a cutting process is implemented using the processing beam 3 (hereinafter, referred to as cutting process region).

FIGS. 1A, 1C and 1F are plan views showing a step of removing the interlayer insulation film 1 through a zigzag scan using the processing beam 3 for processing the insulation film. FIG. 1B is a sectional view taken along an a-a line in FIG. 1A. FIG. 1C is a plan view in the case of repeating the zigzag scan using the processing beam. FIG. 1D is a sectional view taken along a b-b line in FIG. 1C.

First, a case of implementing the zigzag scan using the processing beam 3 once using the processing bema 3 is described referring to FIGS. 1A and 1B. The processing beam 3 having a predetermined beam diameter is irradiated on a surface of the interlayer insulation film 1 so as to zigzag scan the interlayer insulation film 1 using the processing beam 3 while forming the cut hole 1a therein. To describe the zigzag scan, a cutting process region (hereinafter, referred to as processing box) 4 is set by a beam irradiating apparatus, and the set processing box 4 is constantly beam-scanned while the processing beam 3 is being reciprocated in an X direction and minutely moved stepwise in a Y direction. The processing box 4 in the drawings specifically denotes a processing region shown on a setting screen of a beam region designating apparatus.

The processing beam 3 is pulse-irradiated on the interlayer insulation film 1 at sufficiently short time intervals. In the drawings, a reference symbol 3a denotes an irradiation region of each pulse intermittently irradiated and constituting the processing beam 3. The irradiation region is referred to as a spot 3a. The processing beam 3 is focused so that the spots 3a are sufficiently smaller than the processing box 4 in terms of area. The processing beam 3 is intermittently pulse-irradiated so that the spots 3a that are temporally adjacent overlap one another.

When a burning/cutting step using the processing beam 3 is implemented, a trace of the processing beam 3, which is positioned at a final scanning column of all of scanning columns of the processing beam 3, forms a final cut surface 4a of the processing box 4. As shown in FIGS. 1B and C, the final cut surface 4a undergoes a least amount of various residues generated from the cutting process and has a most refined shape.

The processing box 4 is disposed so that the final cut surfaced 4a faces the conductor 2, and more specifically, in a direction where a scanning column direction traverses a cut section of the conductor 2. Thereby, a region 2c of the conductor 2 in contact with the final cut surface 4a is electrically isolated from a region 4d not in contact therewith and other wiring structures. In FIGS. 1B and 1C, a reference symbol 2a shows a cut end surface of the conductor 2 formed in the conductor 2 by the final cut surface 4a.

A reference symbol 1b denotes a side surface of the cut hole 1a and has a shape tilted slightly inward relative to the irradiation direction as a result of a characteristic of the processing beam 3 irradiated in the focused manner. In the example shown in FIG. 1A, the scan using the processing beam 3 is implemented once as described.

During a period when the irradiation of the processing beam 3 is commenced until it is terminated, the processing beam 3 is irradiated on the interlayer insulation film 1 and the conductor 2 so that the interlayer insulation film 1 and the conductor 2 are cut. At that time, a cut depth is increased as the number of the spots 3a subjected to the irradiation in a superposing manner is increased. The processing beam 3 is irradiated on the spots 3a in the state where they partially overlap with one another. Because of that, the cutting depth at a point at which the cutting process is terminated (positioned on the final-cut-surface-4a side) is larger than the cutting depth a point at which the cutting process is commenced (positioned on another cut-surface side other than the final-cut-surface-4a side). Therefore, when the cut surface is observed, a bottom section thereof has a shape tilted from the cutting commencing point toward the cutting terminating point (final cut surface 4a).

In the interlayer insulation film 1 and the conductor 2 thus subject to the cutting process, a conductive residue 2b generated by cutting the conductor 2 is attached to the side surfaces 1b of the cut hole 1a as shown in FIGS. 1C and 1D. The conductive residue 2b is generated from the cut section of the conductor 2, and an amount of the generated conductive residue 2b is increased as a dosage at the beam irradiating position is increased. The dosage represents a unit amount corresponding to an amount of the irradiated beam per unit area, and can be controlled by increasing/decreasing abeam intensity, a time consumed for the beam irradiation, and how many times the spot is subjected to the irradiation at each spot 3a.

The irradiation of the processing beam 3 is characterized in the following conflicting functions, which are: generate the conductive residue 2b from the conductor 2; and vaporize/eliminate the conductive residue 2b attached to the cut surface. A performance of eliminating the conductive residue 2b depends on the dosage of the processing beam 3 in the same manner as the amount of the generated conductive residue 2b. The performance of eliminating the conductive residue 2b is improved as the dosage is increased. Provided that a predetermined cutting depth is obtained, the irradiation time of the processing beam 3 on the respective spots 3a is extended as the number of the repeated scans using the processing beam 3 in the processing box 4 is lessened, as a result of which the dosage supplied to the spots 3a is increased. Thereby, the conductive residue 2b attached to the cut end surface 2a can be more efficiently eliminated by the processing beam 3. More specifically, the cut end surface 2a is more refined as the scan using the processing beam 3 is repeated at a reduced frequency, and the cut end surface 2a can be even more refined when the scan is implemented once.

Because the scan (zigzag scan) is implemented once in the case of the example shown in FIG. 1B, the processing beam 3 can be retained (the irradiation time with respect to the respective spots 3a is extended) at the respective irradiation positions on the respective spots 3a for a relatively long time (for example, at least approximately 10 μsec) so that the sufficient dosage required for the cutting process is secured. The dosage in one scan is thus increased, as a result of which the conductive residue 2b is more generated. However, the dosage of the respective spots 3a in the final cut surface 4a is consequently large enough to eliminate the conductive residue 2b. Because the spots 3a having the dosage enough to eliminate the conductive residue 2b is subjected to the irradiation only once in the final cut surface 4a, the conductor 2 can be cut and the cut surface thereof can be more effectively cleaned though the amount of the generated conductive residue 2b is increased.

However, in the case of securing the dosage in a large number of irradiations, the cleaning effect is weakened, which increases the possibility that the generated conductive residue 2b is attached. Therefore, in the constitution shown in FIG. 1B in which the scan (zigzag scan) is implemented once, the amount of the generated conductive residue 2b on the whole is not reduced, however, the final cut surface 4a (the cut end surface 2a of the conductor 2) can be more effectively cleaned. As a result, the conductive residue 2b as much as to possibly short-circuit the final cut surface 4a (the cut end surface 2a of the conductor 2) is not attached. In other words, the conductor 2 can be continuously electrically insulated though a certain amount of conductive residue 2b is generated.

Next, a case of implementing the zigzag scan using the processing beam 3 a plurality of times is described referring to FIGS. 1C and 1D. In this case, because the scan (zigzag scan) is repeated, the processing beam 3 is retained at the respective irradiation positions on the respective spots 3a for a relatively short time (for example, at most approximately 10 μsec). As a result, the dosage at the respective spots 3a in one scan in this case is smaller than the dosage at the respective spots 3a in the case of the one scan described earlier. As a result, the cleaning effect is weakened though the very amount of conductive residue 2b is lessened. Therefore, it is unlikely that the conductive residue 2b as much as to possibly generate the short circuit in the cut end surface 2a is attached. The conductor 2 can be cut in the reliably electrically insulated state. Thus, when the processing beam 3 (spots 3a) can surely have the dosage capable of eliminating the conductive residue 2b generated by the irradiation of the processing beam 3 on the conductor 2 and attached to the cut end surface 2a facing the final scanning column, the effect of cleaning the conductive residue 2b can be sufficiently maintained despite the plural beam scans.

FIG. 1E shows a sectional view illustrating the example in which the dosage for a spot 3a1 per one irradiation is further reduced in comparison to FIGS. 1C and 1D, wherein the dosage on the whole is surely obtained by increasing the number of the scans though the dosage in the case of irradiating the beam on the spots 3a once is further reduced. In this case, a bottom section 1c of the cut hole 1a is almost flat, however, the effect of cleaning the final cut surface 4a is further weakened because the dosage per one radiation on the spots 3a is not sufficient. As a result, it becomes easier for the conductive residue 2b to be attached to the side surfaces 1b of the cut hole 1a, which increases the possibility that the conductive residue 2b is attached to the final cut surface 4a.

In the foregoing description, the scan using the processing beam 3 follows the zigzag path. In place of that, the scan may be performed in a same direction, for example, as shown in a plan view of FIG. 1F. To describe the scan in the same direction, the beam scan is implemented to the cutting process region 20 with the processing beam 3 being reciprocated in the X direction and minutely shifted stepwise in the Y direction provided that the beam scan is performed in only one way of the reciprocation in the X direction.

In the embodiment 1, there is not need to use the assist gas, which naturally eliminates the need to provide a device of ejecting the assist gas. Accordingly, the apparatus constituted in a simplified manner can be conveniently used in comparison to the method in which the assist gas is used.

In recent years, an interlayer insulation film formed from a material having a low dielectric constant is sometimes used, and it has been pointed out that side etching generated from the assist gas becomes more remarkable when the assist gas is used when the interlayer insulation film formed from the aforementioned material is beam-processed. More specifically, the interlayer insulation film 1 formed from the material having the low dielectric constant generates a larger reaction with the assist gas, which advances the side etching in the horizontal direction more rapidly than the advancement of the processing beam. The side etching is such an unnecessary etching phenomenon in the horizontal direction. The semiconductor processing method according to the embodiment 1, on the contrary, does not at all undergo such an inconvenience (side etching) because the assist gas is not used.

### Embodiment 2

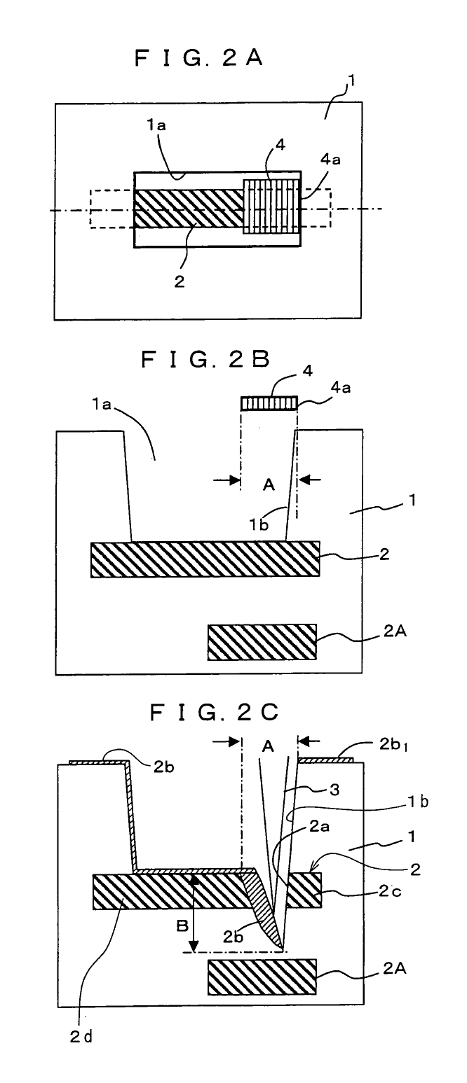

A method (apparatus) of processing the semiconductor apparatus according to an embodiment 2 of the present invention is described referring to FIGS. 2A-2C. First, as shown in FIG. 2A, the cut hole 1a is formed at a position facing the conductor 2 to be processed. The cut hole 1a is formed by cutting the interlayer insulation film 1 using the processing beam 3. At that time, the depth of the cut hole 1a corresponds to a depth which allows the conductor 2 to be exposed out of the bottom section of the cut hole 1a.

When the conductor 2 is exposed, settings of conditions for the beam irradiation, such as the adjustment of an energy of the irradiated beam and the adjustment of a beam scanning speed, are adjusted so that the exposed surface of the conductor 2 becomes flat. Next, the processing box 4 is disposed on an upper side of the exposed conductor 2. When the processing box 4 is set, the final cut surface 4a of the processing box 4 is arranged to fall on the side surface 1b (cut end surface) of the cut hole 1a or partially overlap the inner side of the side surface 1b (inner side of the interlayer insulation film 1). The state in which the processing box 4 is disposed is shown in a sectional view of FIG. 2B.

The conductor 2 is cut as a result of the beam irradiation thereon by means of the scanning method described in the embodiment 1 referring to FIG. 1. At that time, a range on which the processing beam 3 is to be irradiated is restricted by the processing box 4. Thereby, the scan is performed by irradiating the processing beam 3 toward the final cut surface 4a in a positionally corresponding manner with respect to the side surface 1b of the cut hole 1a of the interlayer insulation film 1, and, in the final cut surface, the scan is performed using the both ways or one way along the planar direction of the cut end surface 2a as the final scanning column. Then, the beam scan is terminated when the scan of the final cut surface 4a is completed. The final cut surface 4a is beam-scanned only once. As a result, a sectional surface shown in FIG. 2C is obtained. At that time, the beam scan capable of supplying a relatively large dosage is carried out only once to the final cut surface 4a (including the cut end surface 2a of the conductor 2). Thereby, the sufficient cleaning effect can be obtained. As a result, the region 2c of the conductor 2 is electrically insulated from the region 2d and other wiring structure and is prevented from being short-circuited due to the conductive residue 2b.

In order to ensure the electrical isolation of the conductor 2, it is important to electrically isolate the region 2c disposed on the cut-end-surface-2a side of the conductor 2 and a conductive residue 2b₁ disposed thereabove (on the surface of the interlayer insulation film 1) from each other. Therefore, in the embodiment 2, the cut end surface 2a is disposed on the side surface 1b of the cut hole 1a. Thereby, the side surface 1b of the cut surface 1a, to which the conductive residue 2b is hardly attached, is interposed between the region 2c and the conductive residue 2b. Therefore, when a height of the side surface 1b (depth of the cut hole 1a) has a sufficiently large value, the region 2c and the conductive residue 2b₁ can be reliably electrically isolated from each other.

It is unnecessary to use the assist gas in the embodiment 2 as in the embodiment earlier, which naturally eliminates the need to use the assist gas ejecting device. As a result, the apparatus constituted in a simplified manner in comparison to the method not requiring the assist gas can be used. In the semiconductor processing method (apparatus) according to the embodiment 2, wherein the assist gas is not used, the inconvenience mentioned earlier (side etching) is not at all generated.

In the semiconductor processing method (apparatus) according to the embodiment 2, it is important to prevent the conductive residue 2b from attaching to a conductor 2A provided underneath the conductor 2 to be cut in order to avoid the short circuit or any damage with respect to the conductor 2A. In order to do so, a cutting amount B in the vertical direction is controlled. Parameters for controlling the cutting amount B in the vertical direction include the dosage, a spot irradiation time of the processing beam 3 (a length of time when the processing beam is retained on the respective spots 3a), an interval between the adjacent spots 3a, and a processing-box length A, which should be set to optimum values. For example, there is no problem when the dosage: 1 nC/μm² retaining time on the spots 3a: 10 μsec, interval between the adjacent beam spots 3a: 0.01 μm, and processing-box length A: 0.5 μm because the cutting depth B can be controlled to be approximately 1.0 μm.

### Embodiment 3

In the embodiment 2, the side surface 1b of the cut hole 1a formed in the interlayer insulation film 1 was used in order to electrically isolate the conductor 2 from the conductive residue 2b. In such a constitution, the electrical isolation is not insufficient resulting in the short circuit unless the sufficient depth of the cut hole 1a (height of the side surface 1b) can be ensured. Further, it becomes necessary to positionally adjust the side surface 1a and the final cut surface 4a of the processing box 4 with a high accuracy, which requires an additional labor. In contrast to the embodiment 2, the conductor 2 can be electrically isolated from the conductive residue 2b regardless of the depth of the cut hole 1a and without accurately positionally adjusting the side surface 1a and the final cut surface 4a in an embodiment 3 of the present invention. Below is described a method (apparatus) of processing the semiconductor apparatus according to the embodiment 3.

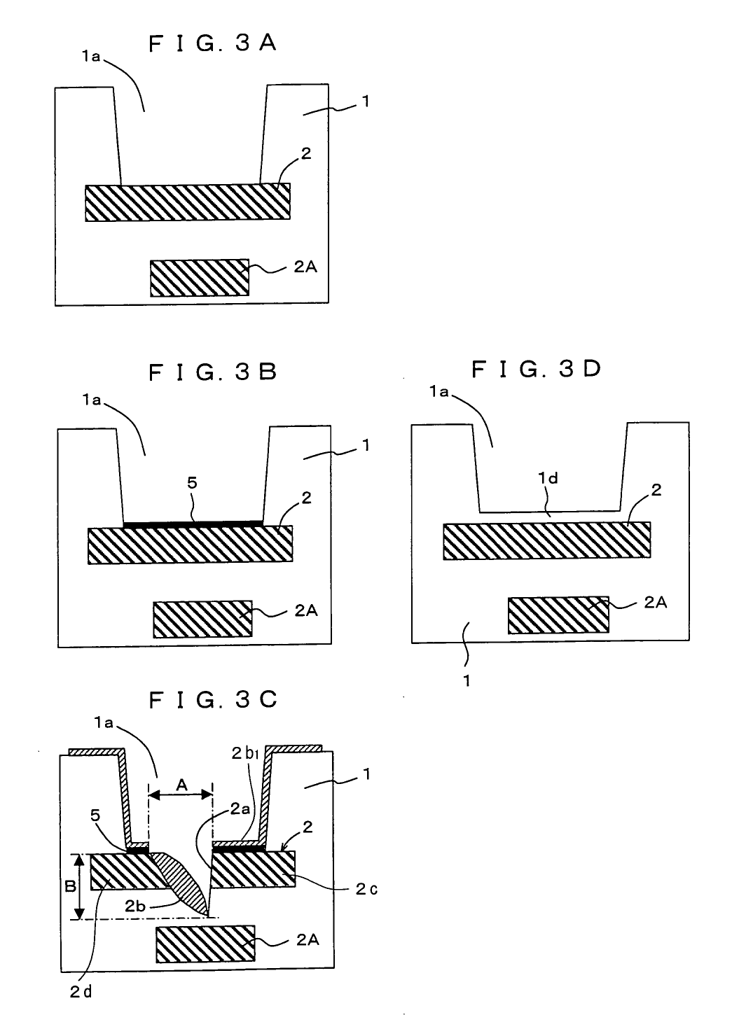

As shown in FIG. 3A, the cut hole 1a is formed in a positionally corresponding manner with respect to the conductor 2 to be processed. The cut hole 1a is formed by cutting the interlayer insulation film 1 using the processing beam 3. At that time, the cut hole 1a is formed deep enough for the conductor 2 to be exposed out of the bottom section of the cut hole 1a.

When the conductor 2 is exposed, the settings of the conditions for the beam irradiation, such as the adjustment of the beam irradiation energy and the adjustment of the beam scanning speed, are adjusted so that the exposed surface of the conductor 2 becomes flat. As shown in FIG. 3B, the surface of the conductor 2 exposed out of the bottom section of the cut hole 1a is covered with an insulation thin film 5.

Then, the conductor 2 is cut from an upper part of the insulation thin film 5 using the processing beam 3 as shown in FIG. 3C. The cutting process is performed in the same manner as in the cutting method described in the embodiment 2 referring to FIGS. 2A-2C, however, the positional correspondence of the final cut surface 4a to the side surface 1b of the cut hole 1a is omitted. In the present embodiment, the final cut surface 4a is disposed at an optional intermediate position between the side surfaces 1b facing each other. Thereby, it becomes unnecessary to attain a high precision in setting the final cut surface 4a, which simplifies the operation.

In the method according to the embodiment 3, the exposed surface of the conductor 2 is covered with the insulation thin film 5. Therefore, though the final cut surface 4a is separated from the side surface 1b and disposed at the center of the bottom section of the cut hole 1a, the presence of the insulation thin film 5 between the region (region on the final-cut-surface-4a side) 2c of the conductor 2 and the conductive residue 2b₁ thereabove enables the region 2c and the conductive residue 2b₁ to be reliably electrically isolated from each other. Thereby, the depth of the cut hole 1a is irrelevant to the improvement of the electrical isolation between the conductor 2 and the conductive residue 2b₁, which alleviates the requirement of the cutting amount B in the vertical direction and threby facilitates the process. Further, an energy level of the processing beam 3 can be reduced because it is not necessary to increase the depth of the cut hole 1a.

As shown in FIG. 3C in place of FIG. 3B, the cutting process may be halted immediately before the surface of the conductor 2 is exposed so as to leave an insulation thin film 1d. The insulation thin film 1d exerts a function similar to that of the insulation thin film 5. After the insulation thin film 1d is formed, the cutting process is performed to the conductor 2 from an upper part of the insulation layer thin film 1d in the same manner as in FIG. 3C.

### Embodiment 4

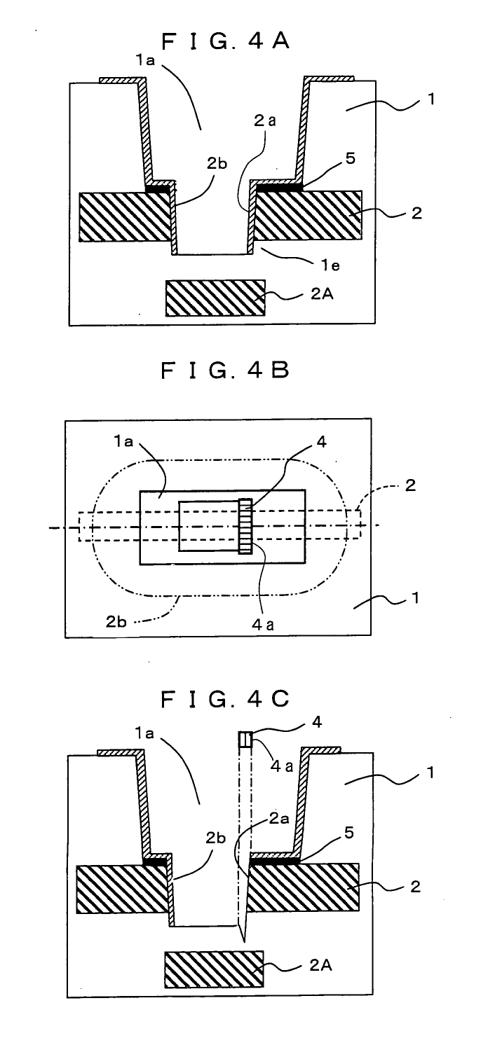

An embodiment 4 of the present invention relates to a method (apparatus) of processing the semiconductor apparatus wherein the cut surface of the conductor is cleaned and then electrically isolated. A sectional view of FIG. 4A shows a state where the conductor 2 is ground through to a region 1e of the interlayer insulation film 1 beneath the conductor 2 subsequent to the implementation of a process similar to the illustrations of FIGS. 3A and 3B. More specifically, the cut hole 1a is formed using the processing beam 3 in the surface of the interlayer insulation film 1 disposed on the conductor 2 to be processed so that a part of the conductor 2 is exposed, the exposed surface of the conductor 2 is covered with the insulation thin film 5, and the processing beam 3 is irradiated from the upper part of the insulation thin film 5 so as to perform the cutting process to the conductor 2 as shown in FIG. 4A. In the cutting process, the number of the irradiations of the processing beam 3 with respect to the cut end surface 2a may or may not be restricted as described in the embodiments 1 and 2 (only once). Therefore, the conductive residue 2b is attached to and remains in the cut surface of the conductor 2 (including the cut end surface 2a corresponding to the final cut surface 4a), which may result in the generation of the short circuit.

Therefore, the processing box 4 is reset after the conductor is cut as shown in FIGS. 4B and 4C. More specifically, the processing box 4 is disposed so that the conductive residue 2b on the cut end surface 2a is subjected to a cleaning process and thereby eliminated. The processing box 4 is specifically disposed in such manner that the beam scan position falls on a position at which the cut end surface 2a is cut. At that time, the processing box 4 having a width larger than that of the conductor 2 is set in order to ensure the cleaning effect.

After the processing box 4 is set, a cleaning beam 3′ is irradiated again on the cut end surface 2a so that the conductive residue 2b on the cut end surface 2a is eliminated. The cleaning beam 3′ is irradiated in the same manner as the processing beam 3 in the embodiments 1 and 2. In such a manner, the conductive residue 2b on at least the cut end surface 2a can be eliminated, and the region 2c of the conductor 2 can be thereby electrically isolated from the region 2d and other wiring structures without fail. When the cleaning process is carried out, the cutting depth in the vertical direction is controlled by adjusting conditions for irradiating the cleaning beam 3′ so that the conductor 2A underneath the layer to be cut can be protected from any damage.

### Embodiment 5

In the embodiment 4, the processing box 4 for the cleaning process is additionally set. In a method (apparatus) of processing the semiconductor apparatus according to an embodiment 5 of the present invention described below, the labor of additionally setting the processing box 4 is saved by using the processing box 4 set for the cutting process also as the processing box 4 for the cleaning process. In order to use the processing box 4 for the additional purpose, the processing box 4 is provided with a shift function set therein, which enables the processing box 4 to be shifted with a shape thereof being maintained. In the embodiment 5, the shift function of the processing box 4 (shift function of the processing beam 3) is used so as to clean the cut end surface 2a.

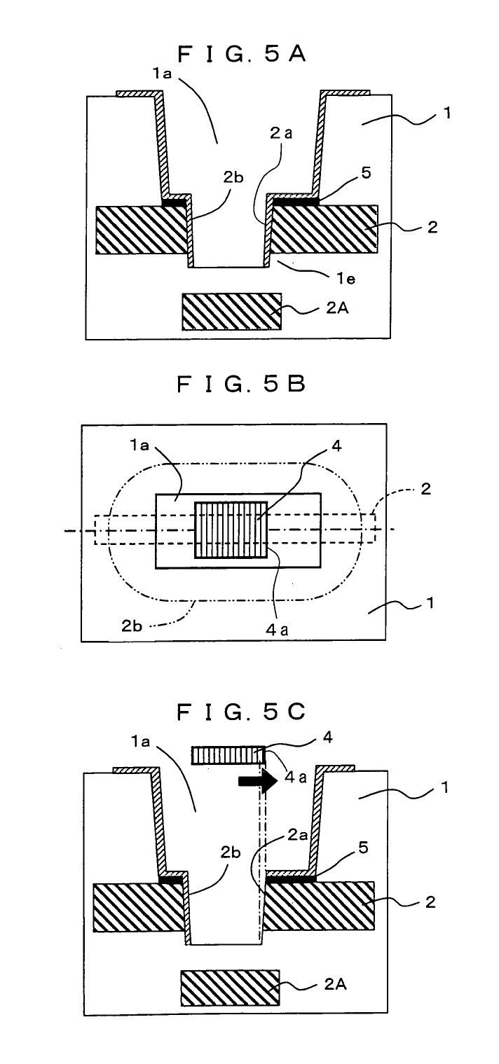

A sectional view of FIG. 5A shows a state where the conductor 2 is ground through to the region 1e of the interlayer insulation film 1 underneath the conductor 2 subsequent to the implementation of a process similar to the illustrations of FIGS. 3A and 3B. More specifically, the cut hole 1a is formed using the processing beam 3 in the surface of the interlayer insulation film in the positinally corresponding manner with respect to the conductor 2 to be processed so that a part of the conductor 2 is exposed, and the insulation thin film 5 for covering the exposed surface of the conductor 2 is formed.

Next, as shown in FIG. 5A, the cutting process is carried out to the conductor 2 using the processing beam 3 from the upper part of the insulation thin film 5. At that time, the final cut surface 4a of the processing box 4 is not positionally aligned to the side surface 1a of the cut hole 1, but disposed at an optional position at the central part of the cut hole 1 though not shown. As a result of the cutting process, it is possible that the conductive residue 2b is attached to the cut end surface 2a resulting in the generation of the short circuit.

In order to deal with the possibility, as shown in FIGS. 5B and 5C, the cleaning beam 3′ is irradiated while the processing box 4 is being shifted in order to clean and eliminate the conductive residue 2b on the cut end surface 2a. The processing box 4 is moved in a direction where the final cut surface 4a of the processing box 4 set for the cutting process is close to the cut-end-surface-2 side.

The processing box 4 set for the cutting process is arranged to have a width larger than a box width of the conductor 2 (width of the final cut surface 4a) to be suitably used for the cleaning, which realizes the reliable cleaning.

Thereby, the spots 3a of the cleaning beam 3′ are gradually moved toward the final cut surface 2a. Then, when the processing beam is irradiated on the spots 3a once in the final cut surface 4a and the cut end surface 2a is thereby cleaned, the shift of the processing box 4 and the beam irradiation on the spots 3a are terminated. A horizontal arrow in FIG. 5C shows a direction where the processing box 4 is moved.

The conductive residue 2b on the cut end surface 2a of the conductor 2 is eliminated in the cleaning process thus implemented, and the region 2c of the conductor 2 is thereby electrically isolated from the region 2d and other wiring structures. A reference symbol C denotes a cleaning surface.

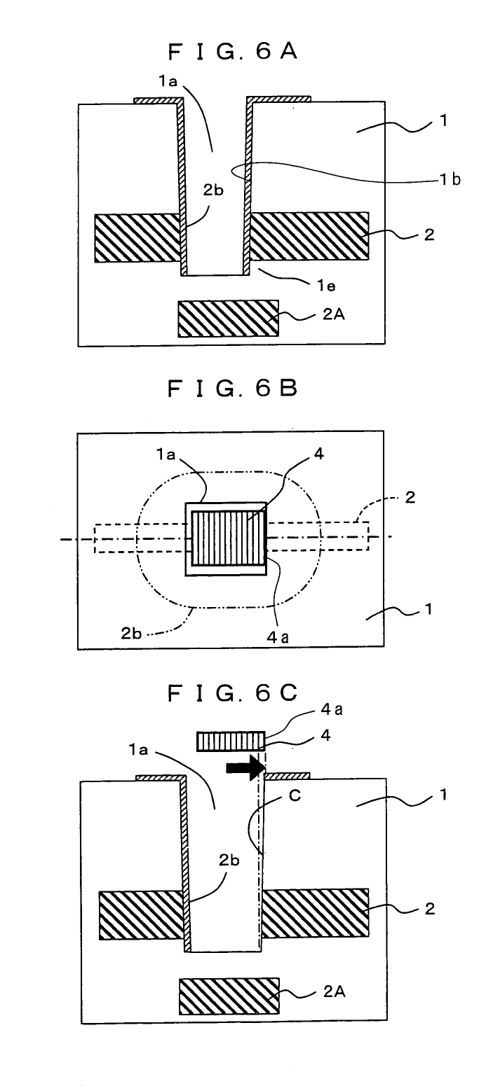

FIG. 6 shows another example of cleaning the cut end surface 2a and the like using the shift function of the processing box 4. The cut hole 1a has a longer dimension in the vertical direction. It is not necessary to additionally form the insulation thin film 5 on the conductor 2. In the case of the cut hole 1a having a sufficiently large depth, the conductive residue 2b on the side surface 1b of the cut hole 1a of the interlayer insulation film 1 and the cut end surface 2a of the conductor 2 can be cleaned and eliminated by the shift of the processing box 4 without providing the insulation thin film 5.

In the case of the present embodiment, the shift function of the processing box 4 is utilized, and the removal of the conductor and the cleaning process are basically implemented through the consecutive irradiations of the processing beam 3 and the cleaning beam 3′. Therefore, any damage generated on the conductor and the like by the irradiations of the processing beam 3 and the cleaning beam 3′ can be limited to a minor level. As a result, any possible damage on the conductor 2A beneath the conductor to be cut can be reduced without tightening the beam conditions for controlling the depth.

### Embodiment 6

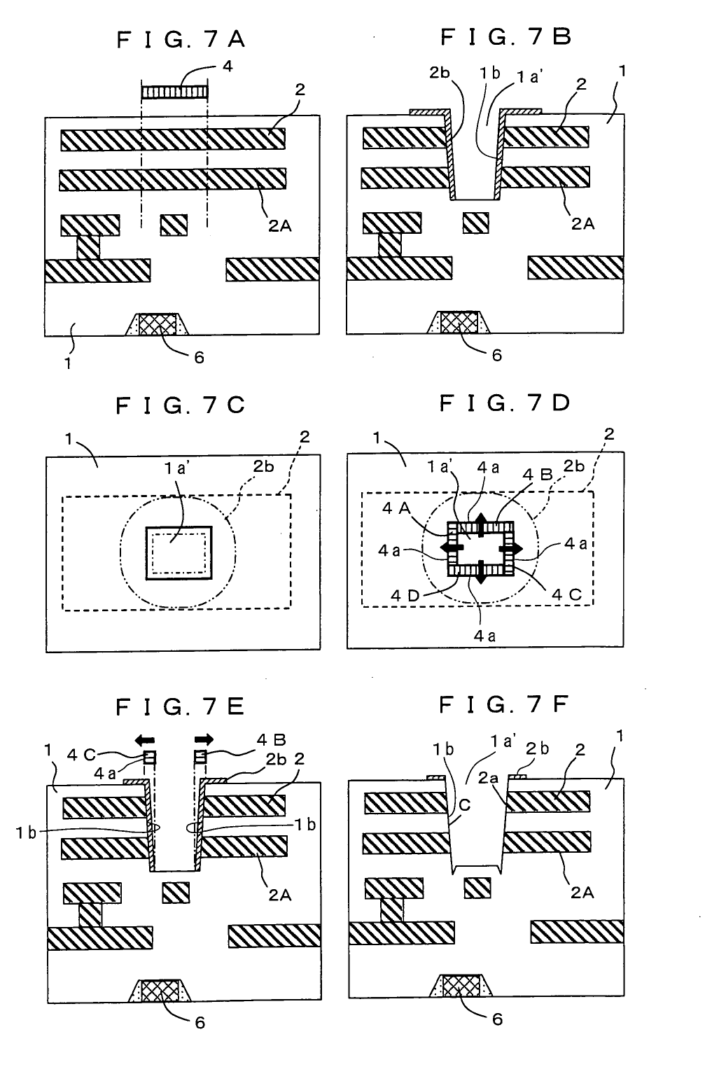

In a method (apparatus) of processing the semiconductor apparatus according to an embodiment 6 of the present invention, the present invention is implemented to the formation of a through hole at the central part in the width direction of the conductor 2 in place of the cutting process of the conductor 2 having the large width. Here is described an example in which a cut hole 1a′ having a through-hole shape is formed in two conductors having a large width. A section view of FIG. 7A shows a state where the processing box 4 is disposed at a position at which the cut hole 1a′ is planned to be formed in the case of forming the cut hole 1a′ having a rectangular shape into two conductors 2 and 2A having a large width embedded as two layers in the interlayer insulation film 1. A reference numeral 6 shown in the drawing denotes a transistor.

Next, as shown in FIGS. 7B and 7C, the processing box 4 is set and then the processing beam 3 (not shown) is irradiated for scan so that a part of the conductor 2 and a part of the conductor 2A are simultaneously cut and eliminated while the rectangular cut hole 1a′ is being formed in the interlayer insulation film 1. When the methods described in the embodiments 2 and 3 are not implemented, the conductive residue 2b is unfavorably attached to the respective side surfaces 1b of the cut hole 1a′.

Next, as shown in FIGS. 7D and 7E, processing boxes 4A, 4B, 4C and 4D for the cleaning process are provided on the four side surfaces of the formed cut hole 1a′. The final cut surfaces 4a of the processing boxes 4A through 4D for the cleaning process are positionally aligned to the side surfaces 1b of the cut hole 1a′ where the conductive residue 2b is generated. Then, after the cleaning processing boxes 4A through 4D are set, the cleaning beam 3′ is irradiated for scan along the processing boxes 4A through 4D so that the conductive residue 2b on the respective side surfaces 1b of the cut hole 1a′ (including the cut end surface 2a) is cleaned and eliminated. A reference symbol C shown in the drawing denotes a cleaning surface. As a result, as shown in FIG. 7F, the upper and lower conductors 2 and 2a are electrically isolated from each other. It is desirable that the scan operations of the processing boxes 4A through 4D be simultaneously executed, however, they may be sequentially executed one by one or two each. The cleaning surface C is preferably covered with an insulator.

### Embodiment 7

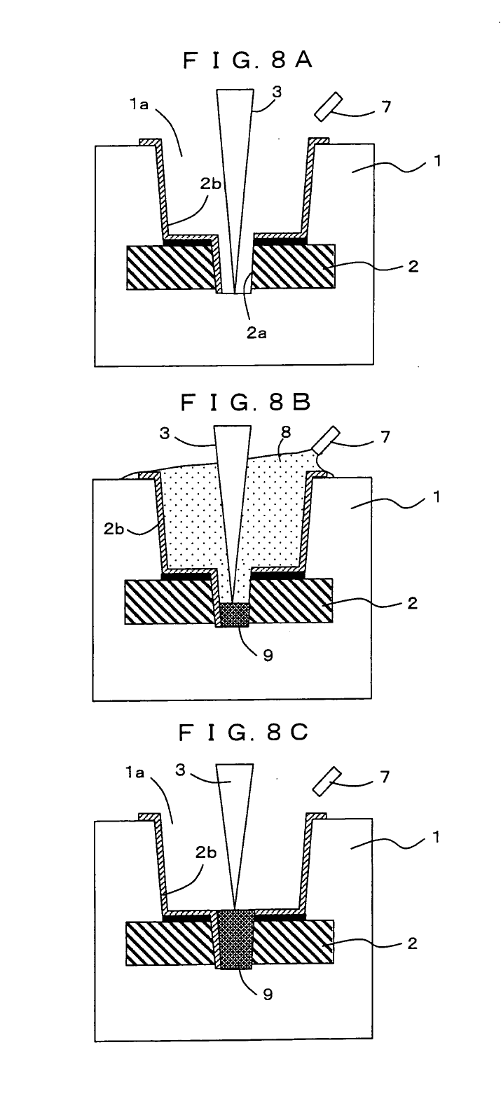

An apparatus for processing the semiconductor apparatus according to an embodiment 7 of the present invention relates to an insulator deposit subsequent to the cutting process of the conductor. FIG. 8A shows a state where the cutting process of the conductor 2 using the processing beam 3 is completed as described. When the cutting process is terminated can be judged based on contrast, an end point tool such as a stage current monitor, visual check of an image, dosage and the like.

Next, as shown in FIG. 8b, a gas 8 for the insulator deposit is supplied into the cut hole 1a from a gas nozzle 7 while the processing beam 3 is being irradiated on the bottom section of the cut hole 1a so that an insulator 9 is deposited at the beam irradiating position. Further, the processing beam 3 is continuously increased as shown in FIG. 8C in the state where the insulator 9 is deposited so that the insulator 9 is grown, and then, the insulation is completed.

As described, according to the present embodiment, the cutting process of the conductor 2 and the deposit of the insulator 9 are carried out in a sequence of processing processes. When the cutting process and the deposit of the insulation are thus serially carried out, any burden in the operation and the processing time can be reduced.

In some cases, two kinds of gasses are used when the insulator 9 is deposited. A first gas is supplied in advance so that the conductive residue 2b is ejected from the cut hole 1a. Around the time when the cutting process of the conductor 2 is completed, a second gas is supplied so that the insulator is deposited at the cut section, and the insulation is completed. As the first gas is used, for example, oxygen. As the second gas is used, for example, TMCTS (Tetra Methyl Cyclo Tetra Siloxane).

### Embodiment 8

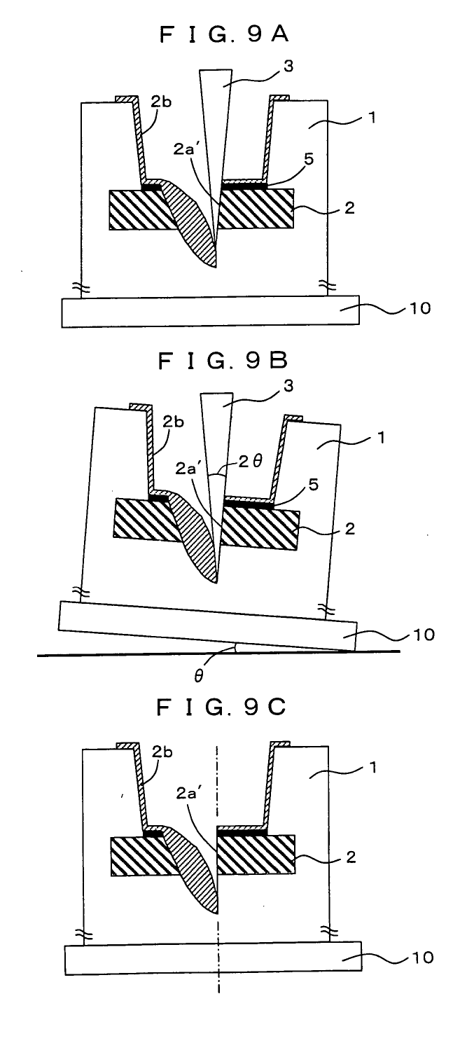

In an apparatus for processing the semiconductor apparatus according to an embodiment 8 of the present invention, a stage 10 of the processing apparatus is tilted so that the sectional surface is finally orthogonally formed. Generally, the processing beam 3, which is focused, has a conical beam shape. The processing beam 3 having the beam shape is used for the cutting process, as shown in FIG. 9A, a cut end surface 2a′ of the conductor 2 formed by the processing beam 3 is tilted to a height direction of the conductor 2. The tilt of the cut end surface 2a′, though very small, is still a possible factor of the attachment of the conductive residue 2b. Therefore, it is preferable that the cut end surface 2a′ be not tilted. In the constitutions shown in FIG. 9, the conductive residue 2b is attached to the cut end surface 2a′. In the constitution shown in FIG. 2, the conductive residue 2b is also attached to the side surfaces 1b of the cut hole 1a.

Therefore, according to the present embodiment, the stage 10 is tilted so that the cut end surface 2a′ formed by the processing beam is orthogonal to the surface of the conductor 2 as shown in FIG. 9B. The shape of the processing beam 3 is different depending on the processing apparatus, beam amount, degree of aperture diaphragm and the like. Provided that an edge angle of the processing beam 3 is 2θ, the stage 10 is horizontally tilted through θ degrees. Then, the cut end surface 2a′ is accurately orthogonal to the surface of the conductor 2. As an approximate standard in the present embodiment, the tilting angle θ is preferably 2 degrees relative to the beam current amount of 100 pA.

FIG. 9C shows a state where the stage 10 is returned to its original horizontal position. In FIG. 9A, the cut end surface 2a′ is tilted through θ degrees from the orthogonal direction relative to the surface of the conductor 2, while, in FIG. 9C, the cut end surface 2a′ is accurately orthogonal to the surface of the conductor 2. As a result, it becomes more difficult for the conductive residue 2b to be attached to the cut end surface 2a′. The method described in the present embodiment can be additionally provided in all of the embodiments described so far.

### Embodiment 9

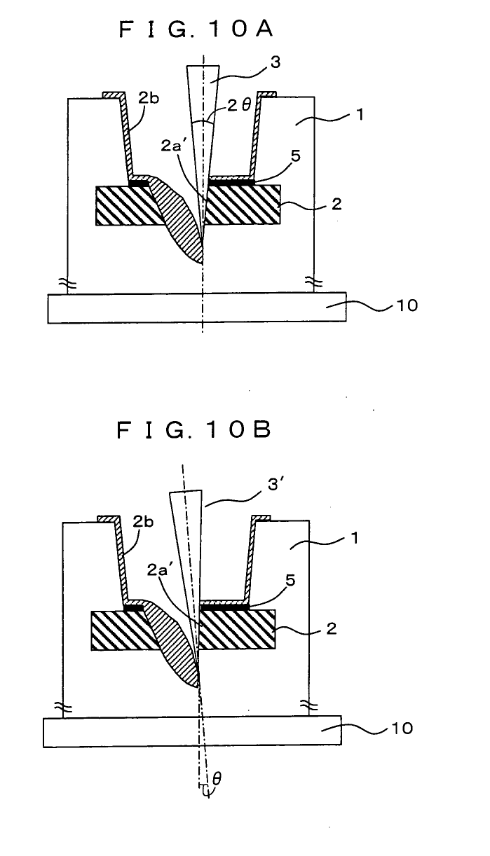

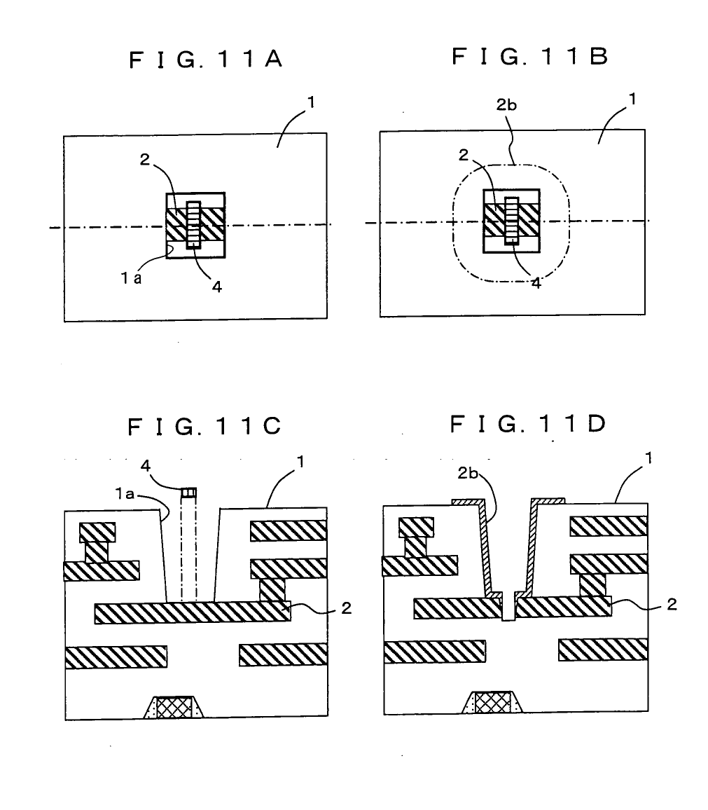

In an embodiment 9 of the present invention, the processing beam 3 of the processing apparatus is tilted so that the cut surface is finally orthogonally formed. As described in the embodiment 8, the processing beam 3 has the conical beam shape, which is shown in FIG. 10. In the embodiment 8, the stage 10 is tilted. On the contrary, the processing beam 3 is tilted in the embodiment 9 as shown in FIG. 10B. Thereby, the cut end surface 2a′ is in parallel with the vertical direction (direction orthogonal to the surface of the conductor 2), which makes it more difficult for the conductive residue 2b to be attached to the cut end surface 2a′. Examples of a method of tilting the processing beam 3 include methods of electrically and magnetically bending the processing beam 3 other than tilting the beam irradiating apparatus.

While there has been described what is at present considered to be preferred embodiments of this invention, it will be understood that various modifications may be made therein, and it is intended to cover in the appended claims all such modifications as fall within the true spirit and scope of this invention.

What is claimed is:

1. A semiconductor apparatus processing method for irradiating a processing beam on a semiconductor apparatus comprising an insulation film and a conductor embedded in the insulation film while scanning the insulation film from a surface side thereof, and burning/cutting the insulation film and the conductor, comprising:
a scanning region setting step for setting a scanning region of the processing beam to a region where a scanning column direction thereof traverses a cut section of the conductor; and
a beam scanning step for irradiating the processing beam for the scan along the set scanning region, wherein
the processing beam used for scanning a final scanning column is supplied with a dosage capable of eliminating a conductive residue generated by the irradiation of the processing beam on the conductor and attached to a cut end surface facing the final scanning column in the beam scanning step.

2. A semiconductor apparatus processing method as claimed in claim 1, wherein
the scanning region is beam-scanned a plurality of times, and the processing beam irradiated on each of the final scanning columns beam-scanned the plurality of times is supplied with the dosage capable of eliminating the conductive residue generated by the irradiation of the processing beam on the conductor and attached to the cut end surface facing the final scanning column in the beam scanning step.

3. A semiconductor apparatus processing method as claimed in claim 1, wherein
the beam scanning step includes:
an insulation film eliminating step in which the processing beam is irradiated on the insulation film covering the cut section of the conductive film so that a cut hole for exposing the cut section of the conductive film is formed in the insulation film; and
a conductive film cutting step in which the conductive film exposed out of a bottom section of the cut hole is cut, wherein
the processing beam used for scanning the final scanning column is supplied with the dosage capable of eliminating the conductive residue generated by the irradiation of the processing beam on the conductor and attached to the cut end surface facing the final scanning column to the scanning beam used for scanning the final scanning column in the conductive film cutting step.

4. A semiconductor apparatus processing method as claimed in claim 3, wherein
the scanning region setting step is implemented after the insulation film eliminating step, and the scanning region is set to a region where the final scanning column falls on a side surface of the cut hole or a region where the final scanning column is disposed slightly closer to an inner side of the insulation film than the side surface of the cut hole in the scanning region setting step.

5. A semiconductor apparatus processing method as claimed in claim 3, further comprising,
a step of forming an insulation thin film for covering the exposed conductive film at the bottom section of the cut hole prior to the conductive film cutting step.

6. A semiconductor apparatus processing method as claimed in claim 3, wherein
the insulation thin film for covering the conductive film remains at the bottom section of the cut hole in the insulation film eliminating step.

7. A semiconductor apparatus processing method as claimed in claim 1, wherein
an insulator depositing gas is supplied to the cut section of the conductor after the beam scanning step is implemented so that an insulator is deposited on the cut section through a reaction generated by the insulator depositing gas with respect to the processing beam.

8. A semiconductor apparatus processing method as claimed in claim 1, wherein
a tilting generated in the cut end surface by a focusing of the processing beam is cancelled in the beam scanning step, and the semiconductor apparatus is tilted in such manner that the cut end surface is vertical to a surface of the insulation film in the beam scanning step.

9. A semiconductor apparatus processing method as claimed in claim 1, wherein
a direction where the processing beam is irradiated is set to such a direction that the cut end surface is vertical to a surface of the insulation film in the beam scanning step.

10. A semiconductor apparatus processing method comprising:
a conductor cutting step in which a processing beam is irradiated on a semiconductor apparatus comprising an insulation film and a conductor embedded in the insulation film from a surface side of the insulation film so that the insulation film and the conductor are burned and cut;
a cleaning scanning region setting step in which a scanning region of a cleaning beam is set to a region where a scanning column direction thereof traverses a cut section of the conductor and a final scanning column thereof falls on a cut end surface of the conductor or the final scanning column is disposed slightly closer to an inner side of the insulation film than a side surface of a cut hole; and
a cleaning beam scanning step for irradiating the cleaning beam for scanning along the set scanning region, wherein
the cleaning beam used for scanning a final scanning column thereof is supplied with a dosage capable of eliminating a conductive residue generated by the irradiation of the processing beam on the conductor and attached to a cut end surface facing the final scanning column in the cleaning beam scanning step.

11. A semiconductor apparatus processing method as claimed in claim 10, wherein
the conductive film cutting step includes:
an insulation film eliminating step in which the processing beam is irradiated on the insulation film covering the cut section of the conductive film so that the cut hole for exposing the cut section of the conductive film is formed in the insulation film;
a step for forming an insulation thin film for covering the exposed conductive film at a bottom section of the cut hole; and
a conductive film cutting step for cutting the conductive film exposed out of the bottom section of the cut hole.

12. A semiconductor apparatus processing method as claimed in claim 10, wherein
The conductive film cutting step includes:
an insulation film eliminating step in which the processing beam is irradiated on the insulation film covering the cut section of the conductive film so that the cut hole for exposing the cut section of the conductive film is formed in the insulation film; and
a conductive film cutting step for cutting the conductive film exposed out of the bottom section of the cut hole, wherein
an insulation thin film for covering the conductive film remains at a bottom section of the cut hole in the insulation film eliminating step.

13. A semiconductor apparatus processing method as claimed in claim 10, wherein
the conductor cutting step includes:
a processing beam scanning region setting step for setting a scanning region of the processing beam to a region where a scanning column direction thereof traverses the cut section of the conductor; and
a processing beam scanning step for irradiating the processing beam for scanning along the set scanning region, wherein
the scanning region of the processing beam is shifted so as to set the scanning region of the cleaning beam in the cleaning scanning region setting step, and the cleaning beam is used for the scan along the scanning region of the cleaning beam set by shifting the scanning region of the processing beam in the cleaning beam scanning step.

14. A semiconductor apparatus processing method as claimed in claim 10, wherein
an insulator depositing gas is supplied to the cut section of the conductor after the cleaning beam scanning step is implemented so that an insulator is deposited on the cut section through a reaction generated by the insulator depositing gas with respect to the cleaning beam.

15. A semiconductor apparatus processing method as claimed in claim 10, wherein
a tilting generated in the cut end surface by a focusing of the cleaning beam is cancelled and the semiconductor apparatus is tilted in such manner that the cut end surface is vertical to a surface of the insulation film in the cleaning beam scanning step.

16. A semiconductor apparatus processing method as claimed in claim 10, wherein
a direction where the cleaning beam is irradiated is set to such a direction that the cut end surface is vertical to a surface of the insulation film in the cleaning beam scanning step.

17. A semiconductor apparatus processing apparatus for irradiating a processing beam on a semiconductor apparatus comprising an insulation film and a conductor embedded in the insulation film while scanning the insulation film from a surface side thereof and burning/cutting the insulation film and the conductor, comprising:
a scanning region setting device for setting a scanning region of the processing beam to a region where a scanning column direction thereof traverses a cut section of the conductor; and
a beam scanning device for irradiating the processing beam for scanning along the set scanning region, wherein
the beam scanning device supplies a dosage capable of eliminating a conductive residue generated by the irradiation of the processing beam on the conductor and attached to the cut end surface facing a final scanning column to the processing beam used for scanning the final scanning column.

18. A semiconductor apparatus processing apparatus as claimed in claim 17, wherein
the beam scanning device beam-scans the scanning region a plurality of times and supplies the processing beam irradiated on each of the final scanning columns beam-scanned the plurality of times with the dosage capable of eliminating the conductive residue generated by the irradiation of the processing beam on the conductor and attached to the cut end surface facing the final scanning column.

19. A semiconductor apparatus processing apparatus as claimed in claim 17, wherein
the beam scanning device includes:
an insulation film eliminating device for forming a cut hole for exposing the cut section of the conductive film in the insulation film by irradiating the processing beam on the insulation film covering the cut section of the conductive film; and
a conductive film cutting device for cutting the conductive film exposed out of a bottom section of the cut hole, wherein
the conductive film cutting device supplies the processing beam used for scanning the final scanning column with the dosage capable of eliminating the conductive residue generated by the irradiation of the processing beam on the conductor and attached to the cut end surface facing the final scanning column.

20. A semiconductor apparatus processing apparatus as claimed in claim 19, wherein
the scanning region setting device sets the scanning region after the insulation film is eliminated by the insulation film eliminating device, and the scanning region setting device sets the scanning region to a region where the final scanning column falls on a side surface of the cut hole or a region where the final scanning column is disposed slightly closer to an inner side of the insulation film than the side surface of the cut hole.

21. A semiconductor apparatus processing apparatus as claimed in claim 19, further comprising an insulation film forming device for forming an insulation thin film for covering the conductive film exposed out of the bottom section of the cut hole prior to the conductive film.

22. A semiconductor apparatus processing apparatus as claimed in claim 19, wherein
the insulation film eliminating device has an insulation thin film for covering the conductive film remain at the bottom section of the cut hole.

23. A semiconductor apparatus processing apparatus as claimed in claim 17, wherein
an insulator depositing gas is supplied to the cut section of the conductor after the beam scan is implemented using the processing beam so that an insulator is deposited on the cut section through a reaction generated by the insulator depositing gas with respect to the processing beam.

24. A semiconductor apparatus processing apparatus as claimed in claim 17, wherein
the beam scanning device cancels a tilting generated in the cut end surface by a focusing of the processing beam and tilts the semiconductor apparatus in such manner that the cut end surface is vertical to a surface of the insulation film.

25. A semiconductor apparatus processing apparatus as claimed in claim 17, wherein
the beam scanning device sets a direction where the processing beam is irradiated to such a direction that the cut end surface is vertical to a surface of the insulation film.

26. A semiconductor apparatus processing apparatus comprising:
a conductor cutting device for irradiating a processing beam on a semiconductor apparatus comprising an insulation film and a conductor embedded in the insulation film from a surface side thereof so that the insulation film and the conductor are burned and cut;
a cleaning scanning region setting device for setting a scanning region of a cleaning beam to a region where a scanning column direction thereof traverses a cut section of the conductor and a final scanning column thereof falls on a cut end surface of the conductor or the final scanning column is disposed slightly closer to an inner side of the insulation film than a side surface of a cut hole; and
a cleaning beam scanning device for irradiating the cleaning beam for scanning along the set scanning region, wherein
the cleaning beam scanning device supplies a dosage capable of eliminating a conductive residue generated by the irradiation of the processing beam on the conductor and attached to the cut end surface facing the final scanning column to the cleaning beam used for scanning the final scanning column.

27. A semiconductor apparatus processing apparatus as claimed in claim 26, wherein
the conductive film cutting device includes:
an insulation film eliminating device for forming a cut hole for exposing the cut section of the conductive film in the insulation film by irradiating the processing beam on the insulation film covering the cut section of the conductive film;
an insulation thin film forming device for forming an insulation thin film for covering the exposed conductive film at a bottom section of the cut hole; and
a conductive film cutting device for cutting the conductive film exposed out of the bottom section of the cut hole.

28. A semiconductor apparatus processing apparatus as claimed in claim 26, wherein
the conductive film cutting device includes:
an insulation film eliminating device for forming a cut hole for exposing the cut section of the conductive film in the insulation film by irradiating the processing beam on the insulation film covering the cut section of the conductive film; and
a conductive film cutting device for cutting the conductive film exposed out of a bottom section of the cut hole, wherein
the insulation film eliminating device has an insulation thin film for covering the conductive film remain at the bottom section of the cut hole.

29. A semiconductor apparatus processing apparatus as claimed in claim 26, wherein
the conductor cutting device includes:
a processing beam scanning region setting device for setting a scanning region of the processing beam to the region where the scanning column direction thereof traverses the cut section of the conductor; and
a processing beam scanning device for irradiating the processing beam for scanning along the set scanning region, wherein
the cleaning scanning region setting device shifts the scanning region of the processing beam to thereby set the scanning region of the cleaning beam, and
the cleaning beam scanning device executes the scan using the cleaning beam along the scanning region of the cleaning beam set by shifting the scanning region of the processing beam.

30. A semiconductor apparatus processing apparatus as claimed in claim 26, wherein
an insulation depositing gas is supplied to the cut section of the conductor so that an insulator is deposited on the cut section through a reaction generated by the insulation depositing gas with respect to the cleaning beam after the cleaning beam is used for the scan.

31. A semiconductor apparatus processing apparatus as claimed in claim 26, wherein
the cleaning beam scanning device cancels a tilting generated in the cut end surface by focusing the cleaning beam and tilts the semiconductor apparatus in such manner that the cut end surface is vertical to a surface of the insulation film.

32. A semiconductor apparatus processing apparatus as claimed in claim 26, wherein
the cleaning beam scanning device sets a direction where the processing beam is irradiated to such a direction that the cut end surface is vertical to a surface of the insulation film.
